(19) United States
(12) Patent Application Publication
(10) Pub. No.: US 2020/0259324 A1
(43) Pub. Date: Aug. 13, 2020

(54) SUPPLY-SIDE OUTPUT OVER-CURRENT PROTECTION TECHNIQUES

(71) Applicant: Analog Devices, Inc., Norwood, MA (US)

(72) Inventor: Brian Beucler, Sandown, NH (US)

(21) Appl. No.: 16/788,438

(22) Filed: Feb. 12, 2020

Related U.S. Application Data
(60) Provisional application No. 62/805,169, filed on Feb. 13, 2019.

(51) Int. Cl. H02H 9/02; H03F 1/52

(52) U.S. Cl. CPC H02H 9/025; H03F 2200/426; H03F 1/52

(57) ABSTRACT

The present disclosure provides techniques for supply-side current protection of a load. In an example, an over-current protection circuit can include a first current-limiting circuit coupled to a first supply rail and configured to supply power to the load, and a second current-limiting circuit coupled to a second supply rail and configured to supply the power to the load in cooperation with the first current-limiting circuit.

### TECHNICAL FIELD OF THE DISCLOSURE

The present disclosure is related to current limiting and more particularly to limiting output current of an amplifier or similar device from a supply path of the device to provide output over-current protection.

### BACKGROUND

Active devices that provide a voltage and current can be susceptible to damage when overloaded, for example by a short circuit from output to ground or to a supply rail. Such devices can include amplifiers such as operational amplifiers. Some amplifiers have short-circuit protection designed into them, but not all. For example, high-performance amplifiers that can provide rail-to-rail output swing, high speed, high precision, high power, or combinations thereof can suffer performance degradation due to short-circuit or over-current protection being implemented in the signal path of the amplifier. Implementation of over-current or short-circuit protection within the signal path of the amplifier can include a current sensor in the output stage of the amplifier, which can turn off one or more output transistors of the amplifier in a current-limiting mode. Entries into, and exits from, current-limiting by turning off the output transistor can introduce distortion, time-delay, or one or more other artifacts into the signal being amplified by the amplifier, thereby degrading signal amplification performance of the amplifier. As such, current limit protection can be omitted from some products. In many industries, device manufacturers do not consider use of such devices in their products because the lack of short circuit protection can adversely affect robustness and reliability of a product.

### SUMMARY OF THE DISCLOSURE

The present disclosure provides techniques for supply-side current protection of a load. In an example, an over-current protection circuit can include a first current-limiting circuit coupled to a first supply rail and configured to supply power to the load, and a second current-limiting circuit coupled to a second supply rail and configured to supply the power to the load in cooperation with the first current-limiting circuit.

This section is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally an example circuit including supply-side implementation for output short circuit protection of an amplifier circuit according to the present subject matter.

FIG. 2 illustrates generally an example over-current protection circuit according the present subject matter.

FIG. 3 illustrates generally a flowchart of an example method for operating an amplifier to provide output short-circuit protection.

### DETAILED DESCRIPTION

The present inventor has recognized techniques for providing short-circuit protection of amplifiers without interrupting the signal path of the amplifier. Such protection techniques can allow unprotected amplifiers, such as amplifiers providing rail-to-rail output, high speed, high precision, high power, or combinations thereof to be used in applications and anticipate that the amplifier will be exposed to over-current events, such as short-circuit events. Such protection techniques can allow existing unprotected amplifiers to be used in applications and industries that expose electronic products to harsh environments. Such industries can include construction, transportation, mining, petroleum exploration and processing, agriculture, as well as others. Such environments can exposed electronic products to weather, vibration, shock, impacts, chemicals, etc. which can momentarily cause electrical shorts in the products. However, quality standards of product manufacturers can include an expectation that the electronic products are to survive momentary electrical shorts and other over-current events, and continue to operate at full performance.

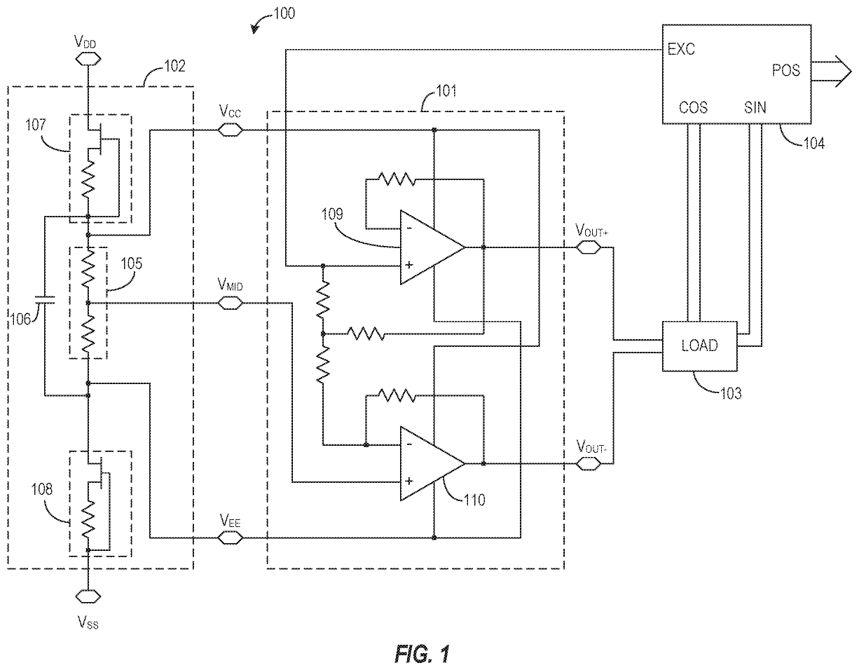

FIG. 1 illustrates generally an example circuit 100 including supply-side implementation for output over-current protection of an amplifier circuit 101 according to the present subject matter. In certain examples, in addition to providing output short circuit protection of the amplifier circuit 101, the supply-side over-current protection does not diminish nominal performance of the amplifier circuit 101. In certain examples, the circuit 100 can include a short-circuit protection circuit 102, the amplifier circuit 101, and a load 103.

Although not limited as such, in FIG. 1, the circuit 100 illustrates an example of a resolver circuit, such as can be used in a position sensor circuit configured for determining a rotational position of a drive shaft. In FIG. 1, the circuit 100 can include a resolver interface circuit 104 such as for exciting an inductive resolver coil of the resolver load 103, receiving the output signals (COS, SIN) of the resolver load 103 and providing a representation (POS) of a position of something coupled to the resolver load 103, such as a representation of an absolute position of the resolver coil relative to resolver windings or incremental position of the resolver coil relative to the resolver windings. In general resolvers can provide position information about a piece of equipment relative to another piece of the equipment or relative to a reference provided and set up in the resolver. Resolvers can be used in very harsh environments as they are very robust mechanically. Applications can include providing position information of one or more various mechanical parts such as a drive shaft of mechanical equipment or of a drive shaft of a vehicle.

In certain examples, the supply-side protection circuit 102 can include first and second current limiting circuits 107, 108, such as a current limiting diodes. Although not necessary for over-current protection, the supply-side protection circuit 102 can include a voltage divider 105 and a filter capacitor 106. The filter capacitor 106 can be coupled between, and in series with, the first and second current limiting circuits 107, 108. The first current limiting circuit 107 can be coupled to a first supply rail (V_{DD}) and the second current limiting circuit 108 can be coupled to a second supply rail (V_{SS}) such as a ground or analog signal ground. In parallel with the filter capacitor 106, the supply-side protection circuit can include the voltage divider 105 to provide a first voltage supply (V_{CC}), a second voltage supply (V_{EE}), and a third voltage supply or reference bias voltage (V_{MID}) for the amplifier circuit 101. In certain examples, when the current limiting circuits 107, 108 include a current limiting diode, the current limiting circuits 107, 108 can respectively include a “diode-connected” junction field-effect transistor (JFET) with a resistor coupling the gate and source nodes of the JFET such as to provide unidirectional current conduction while the gate-source voltage magnitude is less than a threshold voltage magnitude. In certain examples, the short-circuit or over-current protection of the amplifier output is provided by limiting the current available to the amplifier circuit 101 via V_{CC} and V_{EE}, respectively. The current limit can be set via the selection of the JFET and resistor combination of each current limiting circuit 107, 108. In certain examples, when the JFETs, which are normally-on, pass a certain current, a voltage can be established across the resistor that turns the JFET device off, thereby establishing the current limiting feature. The illustrated example includes two current limiting circuits 107, 108 because the amplifier circuit 101 can both source and sink current, with sourced current coming from V_{CC} and sunk current going into V_{EE}. Amplifier circuits providing a unipolar output may be able to use a single current limiting circuit to provide supply-side output over-current protection.

In certain examples, in addition to protecting the load 103 from over-current events, the current limiting circuits 107, 108 can also protect the power supply providing power to the first and second supply rails (V_{DD}, V_{SS}) should the cause of the over-current event be downstream of the current limiting circuits 107, 108. In some examples, the current limiting circuits can be other current limiting devices instead of a current limiting diode discussed above. Such other current limiting devices can include a single resistance in some examples. In some examples, the current limiting circuits can be programmable or can include a plurality of current limiting diodes having switches to couple each current limiting diode into and out of the supply path of the load. Such an arrangement can allow the current limit of the over-current protection circuit to be programmable or selectable.

In the illustrated example of FIG. 1, but not so limited in general, the amplifier circuit 101 can be configured to receive an excitation signal (EXC) and to provide a differential, amplified version (V_{OUT}+, V_{OUT}−) of the excitation signal (EXC) capable of driving the resolver coil of the resolver load 103. Resolver excitation can vary depending on the make and model of the resolver and the resolver interface. Thus, the excitation signal can vary in terms of voltage swing and frequency, and the power required to drive the resolver coil can vary with the resolver coil impedance. Generally, the excitation signal (EXC) is a sinusoidal signal. The illustrated amplifier circuit 101 is configured to provide an amplified version of the excitation signal (EXC) via a differential signal that can vary between the first and second voltage supply levels (V_{CC}, V_{EE}). The amplifier circuit 101 can include two operational amplifiers 109, 110 that need not include output current limiting or output short circuit protection. However, should one of the outputs (V_{OUT}+, V_{OUT}−) of the amplifier circuit 101 short circuit to one of the supply voltages (V_{CC}, V_{EE}, V_{MID}) or one of the supply rails (V_{DD}, V_{SS}), the supply-side short circuit protection 102 can limit the current available for the amplifier circuit 101 to source or sink. The current limit level can be set to be within the operational limits of the operational amplifiers 109, 110, and such that the operational amplifiers 109, 110 are not damaged by the short circuit. Upon correction of the short circuit, the amplifier circuit 101 can return to normal operation.

In certain examples, amplifier circuit 101 can be a separate IC or package from the short-circuit protection circuit 102, which can be made from external components to retrofit short-circuit protection onto the amplifier circuit 101. The over-current protection circuit 102 of can be used in many applications in addition to the resolver application illustrated in FIG. 1. For example, applications can generally operate with constant current in one or more modes such as drivers for illumination including drivers for LEDs, such as automotive taillight LEDs.

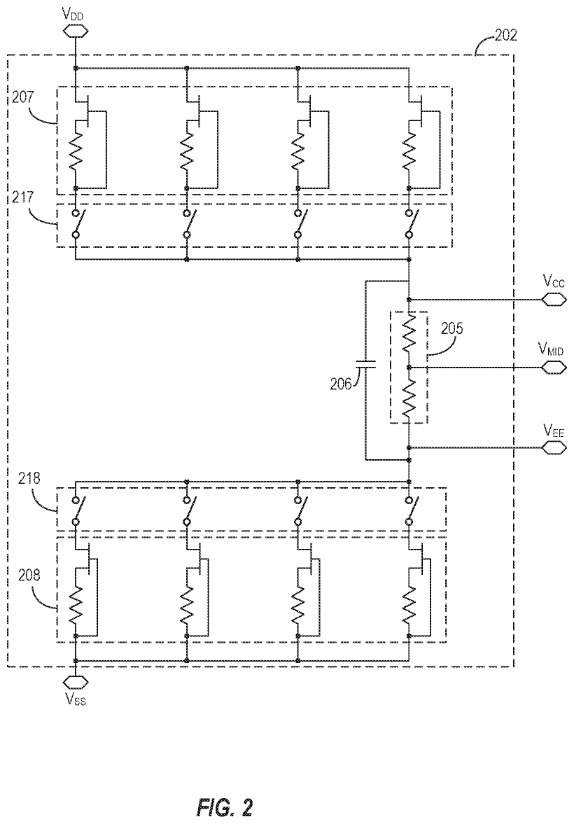

FIG. 2 illustrates generally an example over-current protection circuit 202 according the present subject matter. The over-current protection circuit 202 can be programmable and can include one or more groups of current limiting circuits 207, 208, and one or more groups of switches 217, 218. In certain examples, the over-current protection circuit 202 can include a voltage divider 205 and filter 206 coupled with, or between, the one or more groups of current limiting circuits 207, 208. In some examples, the one or more group of switches 217, 218 can receive command signals from a controller (not shown) of the over-current protection circuit 202. In certain examples, the one or more groups of switches can be actuated manually. The over-current protection circuit 202 can be coupled to one or more supply rails (V_{DD}, V_{SS}) and provide one or more programmable, current-limited, load supply rails (V_{CC}, V_{MID}, V_{EE}). In certain examples, the programmable, current-limited, load supply rails (V_{CC}, V_{EE}) can be the power source for a bi-polar amplifier.

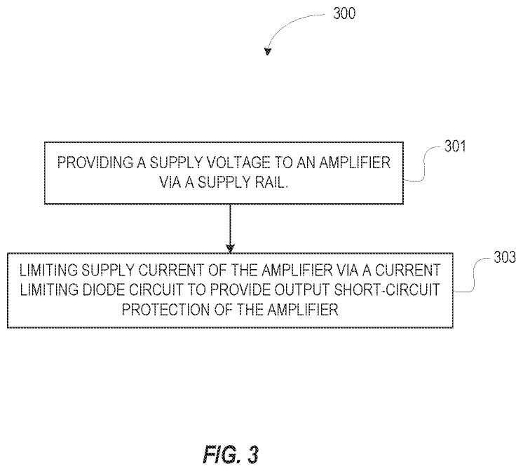

FIG. 3 illustrates generally a flowchart of an example method of operating an amplifier. At 301, supply voltage can be provided to the amplifier via a supply rail. At 303, an output current of the amplifier can be limited via a current limiting diode circuit coupled between the supply rail and a supply input of the amplifier. In certain examples, the amplifier does not include output short-circuit protection such as output short circuit protection implemented in the signal path of the amplifier. In some examples, the current-limiting diode circuit can include a transistor and a resistor arranged to act as a diode when supplying current below a predetermined current limit. As current increases to the current limit, the voltage developed across the resistor can bias the control node of the transistor such that the transistor assumes a high impedance state and limits the current passed from the supply rail. In certain examples, the choice of transistor and resistance value of the resistor can determine the current limit of the current-limiting diode circuit. In certain examples, a current-limiting diode circuit can include a switch to enable the current limiting capabilities of the circuit. In some examples, a number of current-limiting diode circuits can be coupled in parallel and can include one or more switches, such that the current limiting capability is programmable and can be changed on-the-fly.

### VARIOUS NOTES & EXAMPLES

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, the terms “including” and “comprising” are open-ended, that is, a system, device, article, composition, formulation, or process that includes elements in addition to those listed after such a term are still deemed to fall within the scope of subject matter discussed. Moreover, such as may appear in a claim, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of a claim. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. The following aspects are hereby incorporated into the Detailed Description as examples or embodiments, with each aspect standing on its own as a separate embodiment, and it is contemplated that such embodiments can be combined with each other in various combinations or permutations.

What is claimed is:

1. An over-current protection circuit comprising:
a first current limiting circuit coupled to a first supply rail and configured to supply power to a load; and
a second current limiting circuit coupled to a second supply rail and configured to supply the power to the load in cooperation with the first current limiting circuit.

2. The over-current protection circuit of claim 1, wherein the first current limiting circuit includes first current limiting diode comprising a first junction field-effect transistor (JFET).

3. The over-current protection circuit of claim 2, wherein the first current limiting diode includes a resistance coupled between a gate of the first JFET and a source of the first JFET and is configured to modulate a control node of the first JFET to limit current passed by the first current limiting diode circuit.

4. The over-current protection circuit of claim 1, wherein the first current limiting circuit includes a plurality of current limiting devices, each current limiting device of the plurality of current limiting devices selectively coupled between the first supply rail and the load.

5. The over-current protection circuit of claim 1, including a voltage divider, wherein the voltage divider couples the first current limiting circuit with the second current limiting circuit.

6. The over-current protection circuit of claim 5, including a filter coupled in parallel with the voltage divider.

7. The over-current protection circuit of claim 1, wherein the second current limiting circuit includes:
a second first current limiting JFET; and
a second resistance coupled between a gate of the second current limiting JFET and a source of the second current limiting JFET and wherein the second resistance is configured to modulate a control node of the second current limiting JFET to limit current passed by the second current limiting diode circuit.

8. A method providing output over-current protection for an amplifier, the method comprising:
providing a representation of an input signal of the amplifier at an output of the amplifier; and
limiting supply current of the amplifier to limit output current of the amplifier when the output of the amplifier is shorted with a supply rail of the amplifier.

9. The method of claim 8, wherein limiting the supply current includes passing supply current thorough a current limiting diode circuit.

10. The method of claim 9, wherein passing supply current thorough a current limiting diode circuit includes passing supply current through a junction field-effect transistor (JFET).

11. The method of claim 10, wherein passing supply current thorough a current limiting diode circuit modulating operation of the JFET via a resistance coupled between a gate of the JFET and a source of the JFET, and pulling the JFET to an “off” state when the supply current reaches a current limit threshold set by selection of the JFET and the resistance.

12. A circuit comprising:
an amplifier configured to receive and input signal at an input and to provide a representation for the input signal at an output; and
an over-current protection circuit configured to provide supply current to the amplifier and to limit the supply current to provide output over-current protection for the amplifier.

13. The circuit of claim 12, wherein the over-current protection circuit includes a first current limiting diode circuit coupled between the amplifier and a first supply rail.

14. The circuit of claim 13, wherein the first current limiting diode circuit includes a first junction field-effect transistor (JFET).

15. The circuit of claim 14, wherein the first current limiting diode circuit includes a first resistance coupled between a gate of the first JFET and a source of the first JFET and is configured to modulate the first JFET to limit current passed by the first current limiting diode circuit.

16. The circuit of claim 15, wherein the over-current protection circuit includes:
a second current limiting diode circuit coupled to a second supply rail; and
a resistor network coupled between, and in series with, the first and second current limiting diode circuits between the first supply rail and the second supply rail.

17. The circuit of claim 16, including a resolver coupled to the output of the amplifier, and wherein the amplifier is configured to drive a coil of the resolver.

18. The circuit of claim 16, wherein the amplifier includes a first operational amplifier and a second operational amplifier;
wherein the output of the amplifier is a differential output;
wherein an output of the first operational amplifier is a first differential output of the amplifier;
wherein an output of the second operational amplifier is a second differential output of the amplifier; and
wherein the first differential output and the second differential output provide the differential output of the amplifier.

19. The circuit of claim 18, wherein the second current limiting diode circuit includes a second JFET and a second resistance coupled between a gate of the second JFET and a source of the second JFET.

20. The circuit of claim 12, wherein the over-current protection circuit includes a first plurality of current limiting diode circuits coupled to a first power rail and configured to supply first power to the amplifier;
wherein the over-current protection circuit includes a second plurality of current limiting diode circuits coupled to a second power rail and configured to supply second power to the amplifier;
wherein a third plurality of current limiting diode circuits of the first plurality of current limiting diode circuits include a respective switch for each current limiting diode circuit of the third plurality of current limiting diode switches;
wherein a fourth plurality of current limiting diode circuits of the second plurality of current limiting diode circuits include a respective switch for each current limiting diode circuit of the fourth plurality of current limiting diode switches; and
wherein the plurality of respective switches are configured to provide a programmable current limit for the amplifier.
